(19) United States
(12) Patent Application Publication
(10) Pub. No.: US 2025/0174431 A1
(43) Pub. Date: May 29, 2025

(54) Apparatus and Method for Splitting Current from Direct-Drive Radiofrequency Signal Generator between Multiple Coils

(71) Applicant: Lam Research Corporation, Fremont, CA (US)

(72) Inventors: Matthew Lowell Talley, Union City, CA (US); Alexander Miller Paterson, San Jose, CA (US); Yuhou Wang, Fremont, CA (US); Richard A. Marsh, San Ramon, CA (US)

(21) Appl. No.: 18/715,676

(22) PCT Filed: Dec. 12, 2022
(86) PCT No.: PCT/US2022/052563

§ 371 Date: May 31, 2024

Related U.S. Application Data
(60) Provisional application No. 63/291,307, filed on Dec. 17, 2021.

(51) Int. Cl. H01J 37/32; H01F 27/28; H03H 7/01

(52) U.S. Cl. CPC H01J 37/3211; H01F 27/28; H01J 37/32174; H03H 7/0115

(57) ABSTRACT

A radiofrequency (RF) power supply system includes a first coil and a second coil. The RF power supply system also includes a first RF power source connected to supply RF signals of a first frequency to both the first coil and the second coil. The RF power supply system also includes a current splitter variable capacitor connected to control a division of the RF signals of the first frequency between the first coil and the second coil. The RF power supply system also includes a second RF power source connected to supply RF signals of a second frequency to the second coil. In some embodiments, the first and second RF power sources are first and second direct-drive RF power sources, respectively, that drive the RF signals of the first and second frequencies, respectively, through first and second reactive circuits, respectively.

### BACKGROUND

Plasma processing systems are used to manufacture semiconductor devices, e.g., chips/die, on semiconductor wafers. In the plasma processing system, the semiconductor wafer is exposed to various types of plasma to cause prescribed changes to a condition of the semiconductor wafer, such as through material deposition and/or material removal and/or material implantation and/or material modification, etc. During plasma processing of the semiconductor wafer, radiofrequency (RF) power is transmitted through a process gas within a chamber to transform the process gas into the plasma in exposure to the semiconductor wafer. Reactive constituents of the plasma, such as radicals and ions, interact with materials on the semiconductor wafer to achieve a prescribed effect on the semiconductor wafer. In some plasma processing systems, generated RF power is transmitted to the process gas by way of a coil positioned outside of the plasma processing chamber. It is within this context that embodiments described in the present disclosure arise.

### SUMMARY

In an example embodiment, an RF power supply system is disclosed. The RF power supply system includes a first coil and a second coil. The RF power supply system also includes a first RF power source connected to supply RF signals of a first frequency to both the first coil and the second coil. The RF power supply system also includes a current splitter variable capacitor connected to control a division of the RF signals of the first frequency between the first coil and the second coil. The RF power supply system also includes a second RF power source connected to supply RF signals of a second frequency to the second coil.

In an example embodiment, an RF power supply system is disclosed. The RF power supply system includes a first RF power source that has an output terminal. The RF power supply system also includes a first reactive circuit that has an input terminal and an output terminal. The input terminal of the first reactive circuit is connected to the output terminal of the first RF power source. The RF power supply system also includes a first coil connected to the output terminal of the first reactive circuit. The RF power supply system also includes a current splitter variable capacitor that has an input terminal and an output terminal. The input terminal of the current splitter variable capacitor is connected to the output terminal of the first reactive circuit. The RF power supply system also includes a second coil connected to the output terminal of the current splitter variable capacitor. The RF power supply system also includes a second RF power source that has an output terminal. The RF power supply system also includes a second reactive circuit that has an input terminal and an output terminal. The input terminal of the second reactive circuit is connected to the output terminal of the second RF power source. The RF power supply system also includes a blocking filter that has an input terminal and an output terminal. The input terminal of the blocking filter is connected to the output terminal of the second reactive circuit. The output terminal of the blocking filter is connected to the second coil.

In an example embodiments, a method is disclosed for supplying RF power to a plasma processing system. The method includes generating RF signals of a first frequency. The method also includes supplying a first portion of the RF signals of the first frequency to a first coil. The method also includes supplying a second portion of the RF signals of the first frequency to a second coil. The method also includes generating RF signals of a second frequency. The method also includes supplying the RF signals of the second frequency to the second coil.

Other aspects and advantages of the embodiments will become more apparent from the following detailed description and the accompanying drawings.

### BRIEF DESCRIPTION OF THE DRAWINGS

FIG. 1 shows an RF power supply system, in accordance with some embodiments.

FIG. 2A shows a schematic of a direct-drive RF signal generator, in accordance with some embodiments.

FIG. 2B shows a plot of a parameter of an example shaped-amplified square waveform generated at the output terminal of the first/second RF power source as a function of time, in accordance with some embodiments.

FIG. 2C shows a plot of a parameter of an example shaped-sinusoidal waveform generated at the output terminal of the first/second reactive circuit as a function of time, in accordance with some embodiments.

FIG. 2D shows a plot of the shaped-sinusoidal waveform corresponding to the shaped-amplified square waveform of FIG. 2B, in accordance with some embodiments.

FIG. 3A shows an example plasma processing system that utilizes the RF power supply system of FIG. 1, in accordance with some embodiments.

FIG. 3B shows a top view of the first coil and the second coil in the plasma processing system of FIG. 3A, in accordance with some embodiments.

FIG. 4 shows a flowchart of a method for supplying RF power to a plasma processing system, in accordance with some embodiments.

FIG. 5 shows a diagram of the system controller, in accordance with some embodiments.

### DETAILED DESCRIPTION

In the following description, numerous specific details are set forth in order to provide a thorough understanding of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

Systems and methods are disclosed herein for splitting RF current of a first frequency between multiple coils of an RF power supply system used to drive a plasma for processing of a substrate, e.g., semiconductor wafer, in combination with transmission of RF current of a second frequency to some of the multiple coils, such that at least one of the multiple coils receives both a portion of the RF current of the first frequency and the RF current of the second frequency. These systems and methods are useful in many plasma processing situations, and are particularly useful in situations where supply of the RF current of the second frequency alone to a given coil is not sufficient to ignite/strike and sustain a plasma having prescribed characteristics. In such situations, the portion of the RF current of the first frequency that is transmitted to the given coil in combination with the RF current of the second frequency serves to support igniting/striking and sustaining of the plasma having the prescribed characteristics. The above-mentioned situation is but one example of many uses and advantages that are possible with the systems and methods disclosed herein.

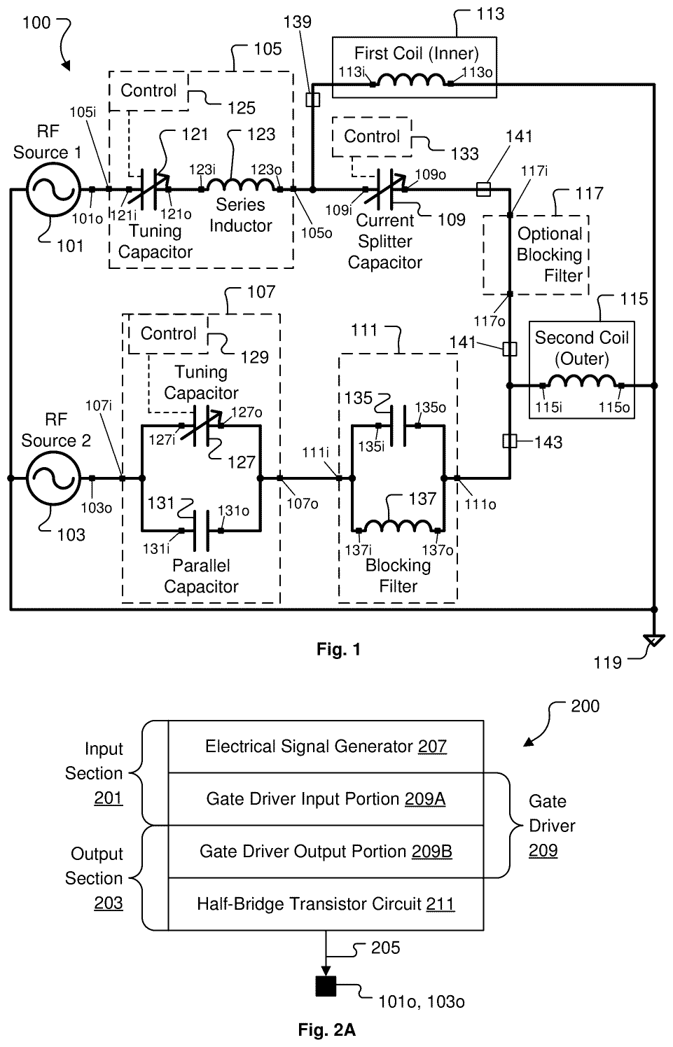

FIG. 1 shows an RF power supply system 100, in accordance with some embodiments. The RF power supply system 100 includes a first coil 113 and a second coil 115. In some embodiments, the first coil 113 is an inner coil and the second coil 115 is an outer coil. In some of these embodiments, each of the first coil 113 (inner coil) and the second coil 115 (outer coil) is a planar-type spiral-shaped coil, with the second coil 115 circumscribing the first coil 113. The first coil 113 has an input terminal 113i and an output terminal 1130. The input terminal 113i of the first coil 113 is connected to receive RF signals of a first frequency from a first RF power source 101. The output terminal 1130 of the first coil 113 is connected to a reference ground potential 119. The second coil 115 has an input terminal 115i and an output terminal 1150. The input terminal 115i of the second coil 115 is connected to receive RF signals of a second frequency from a second RF power source 103. The second RF power source 103 is connected to supply RF signals of the second frequency to the second coil 115. Additionally, the input terminal 115i of the second coil 115 is also connected to receive RF signals of the first frequency from the first RF power source 101, in accordance with a capacitance setting of a current splitter variable capacitor 109 connected between the first RF power source 101 and the second coil 115. The current splitter variable capacitor 109 is connected in parallel with the first coil 113. In this manner, the first RF power source 101 is connected to supply RF signals of the first frequency to both the first coil 113 and the second coil 115, with the current splitter variable capacitor 109 connected to control a division of the RF signals of the first frequency between the first coil 113 and the second coil 115. Also, the output terminal 1150 of the second coil 115 is connected to the reference ground potential 119.

In some embodiments, the RF power supply system 100 includes a first reactive circuit 105 that has an input terminal 105i connected to an output terminal 101o of the first RF power source 101. In this manner, the first RF power source 101 is connected to supply the RF signals of the first frequency through the first reactive circuit 105 to both the first coil 113 and the second coil 115. Also, in some embodiments, the RF power supply system 100 includes a second reactive circuit 107 that has an input terminal 107i connected to an output terminal 103o of the second RF power source 103. In this manner, the second RF power source 103 is connected to supply the RF signals of the second frequency through the second reactive circuit 107 to the second coil 115.

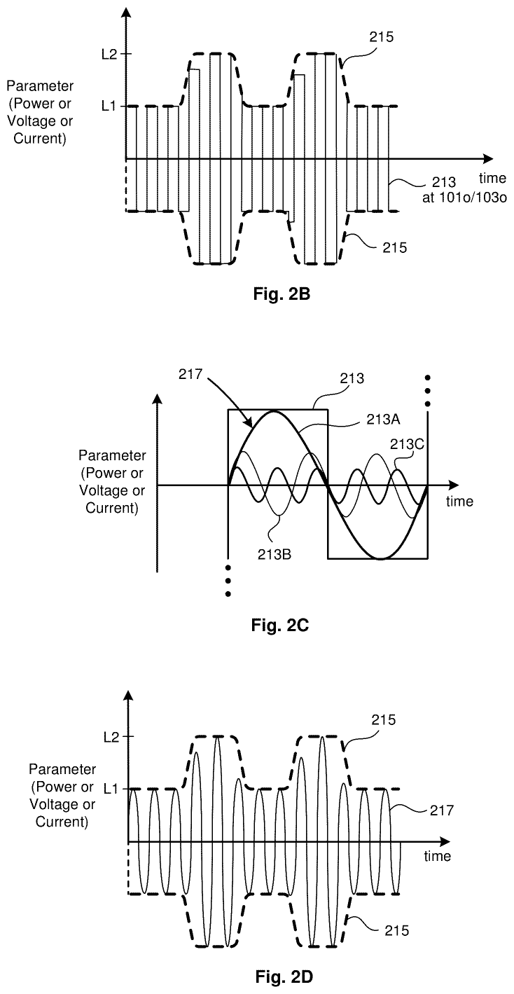

In some embodiments, each of the first RF power source 101 and the second RF power source 103 is a respective direct-drive RF signal generator. FIG. 2A shows a schematic of a direct-drive RF signal generator 200, in accordance with some embodiments. The direct-drive RF signal generator 200 includes an input section 201 and an output section 203. The input section 201 is electrically coupled to the output section 203. For the first RF power source 101, the output section 203 is electrically connected to the output terminal 101o, as indicated by arrow 205. In this manner, for the first RF power source 101, the output section 203 is electrically connected to the first reactive circuit 105, as indicated by the arrow 205. Similarly, for the second RF power source 103, the output section 203 is electrically connected to the second reactive circuit 107, as indicated by the arrow 205. The input section 201 includes an electrical signal generator 207 and an input portion 209A of a gate driver 209. The output section 203 includes a output portion 209B of the gate driver 209 and a half-bridge transistor circuit 211. The input section 201 generates multiple square-wave signals and provides the square-wave signals to the output section 203. The output section 203 generates an amplified square-shaped waveform from the multiple square-wave signals received from the input section 201. The output section 203 also shapes an amplitude envelope, such as a peak-to-peak magnitude, of the amplified square-shaped waveform. For example, a shaping control signal is supplied from the input section 201 to the output section 203 to generate the amplitude envelope. The shaping control signal has multiple voltage values for shaping the amplified square-shaped waveform to generate a shaped-amplified square waveform within the amplitude envelope. For the first RF power source 101, the shaped-amplified square waveform is transmitted from the output section 203 to the first reactive circuit 105. For the second RF power source 103, the shaped-amplified square waveform is transmitted from the output section 203 to the second reactive circuit 107.

Each of the first reactive circuit 105 and the second reactive circuit 107 removes, such as filters out, higher-order harmonics of the shaped-amplified square waveform to generate a shaped-sinusoidal waveform having a fundamental frequency. The shaped-sinusoidal waveform has the same amplitude envelope as the shaped-amplified square waveform. For the first RF power source 101, RF power is transmitted through the output terminal 105o of the first reactive circuit 105 in the form of the shaped-sinusoidal waveform having the fundamental frequency and the amplitude envelope. Similarly, for the second RF power source 103, RF power is transmitted through the output terminal 107o of the second reactive circuit 107 in the form of the shaped-sinusoidal waveform having the fundamental frequency and the amplitude envelope.

FIG. 2B shows a plot of a parameter of an example shaped-amplified square waveform 213 generated at the output terminal 101o/103o of the first/second RF power source 101/103 as a function of time, in accordance with some embodiments. The parameter of the shaped-amplified square waveform 213 is cither power, voltage, or current. FIG. 2B also shows an amplitude envelope 215 (represented by the heavy dashed line) of the shaped-amplified square waveform 213, where the amplitude envelope 215 is generated in accordance with the voltage values indicated by the shaping control signal that is transmitted to the output section 203 of the direct-drive RF signal generator 200. In the example of FIG. 2B, the amplitude envelope 215 is controlled so that an absolute magnitude of the parameter of the shaped-amplified square waveform 213 transitions between a first level L1 (lower level) and a second level L2 (higher level). However, it should be understood that in various processes the amplitude envelope 215 can be controlled to have essentially any desired shape by controlling the voltage supplied to a power rail in the output section 203 as a function of time in accordance with the shaping control signal that is transmitted to the output section 203. For example, in various processes, the shaping control signal can be generated to direct the amplitude envelope 215 to have a continuous wave shape, a triangular shape, a multi-level pulse shape, or essentially any other prescribed controlled shape.

FIG. 2C shows a plot of a parameter of an example shaped-sinusoidal waveform 217 generated at the output terminal 105o/107o of the first/second reactive circuit 105/107 as a function of time, in accordance with some embodiments. The parameter of the shaped-sinusoidal waveform 217 is either power, voltage, or current. The shaped-sinusoidal waveform 217 is based on the shaped-amplified square waveform 213 that is transmitted to the input terminal 105i/107i of the first/second reactive circuit 105/107 as a function of time. The shaped-sinusoidal waveform 217 also has the amplitude envelope 215. The shaped-amplified square waveform 213 is a combination of a fundamental frequency sinusoidal waveform 213A and multiple higher-order harmonic frequency sinusoidal waveforms 213B, 213C, etc. For example, the sinusoidal waveform 213B represents a second order harmonic frequency of the fundamental frequency sinusoidal waveform 213A. And, the sinusoidal waveform 213C represents a third order harmonic frequency of the fundamental frequency sinusoidal waveform 213A. The first/second reactive circuit 105/107 functions to remove the higher-order harmonic frequency sinusoidal waveforms 213B, 213C, etc. from the shaped-amplified square waveform 213, so that just the fundamental frequency sinusoidal waveform 213A is provided as the shaped-sinusoidal waveform 217 at the output terminal 105o/107o of the first/second reactive circuit 105/107 as a function of time.

FIG. 2D shows a plot of the shaped-sinusoidal waveform 217 corresponding to the shaped-amplified square waveform 213 of FIG. 2B, in accordance with some embodiments. For the first RF power source 101, the shaped-sinusoidal waveform 217 at the output terminal 105o of the reactive circuit 105 is transmitted to the first coil 113 and to the second coil 115, in accordance with the capacitance setting of the current splitter variable capacitor 109. For the second RF power source 103, the shaped-sinusoidal waveform 217 at the output terminal 107o of the reactive circuit 107 is transmitted to the second coil 115.

With reference back to FIG. 1, in some embodiments, the first reactive circuit 105 includes an input terminal 105i connected to an output terminal 101o of the first RF power source 101. The first reactive circuit 105 includes a first tuning variable capacitor 121 that has an input terminal 121i connected to the input terminal 105i of the first reactive circuit 105, and in turn to the output terminal 101o of the first RF power source 101. The first reactive circuit 105 also includes an inductor 123 connected in series with the first tuning variable capacitor 121. Specifically, an input terminal 123i of the inductor 123 is connected to an output terminal 1210 of the first tuning variable capacitor 121. An output terminal 1230 of the inductor 123 is connected to an output terminal 105o of the first reactive circuit 105. The output terminal 105o of the first reactive circuit 105 is connected to both an input terminal 113i of the first coil 113 and an input terminal 109i of the current splitter variable capacitor 109. In this manner, the output terminal 1230 of the inductor 123 is connected to both the first coil 113 and the input terminal 109i of the current splitter variable capacitor 109.

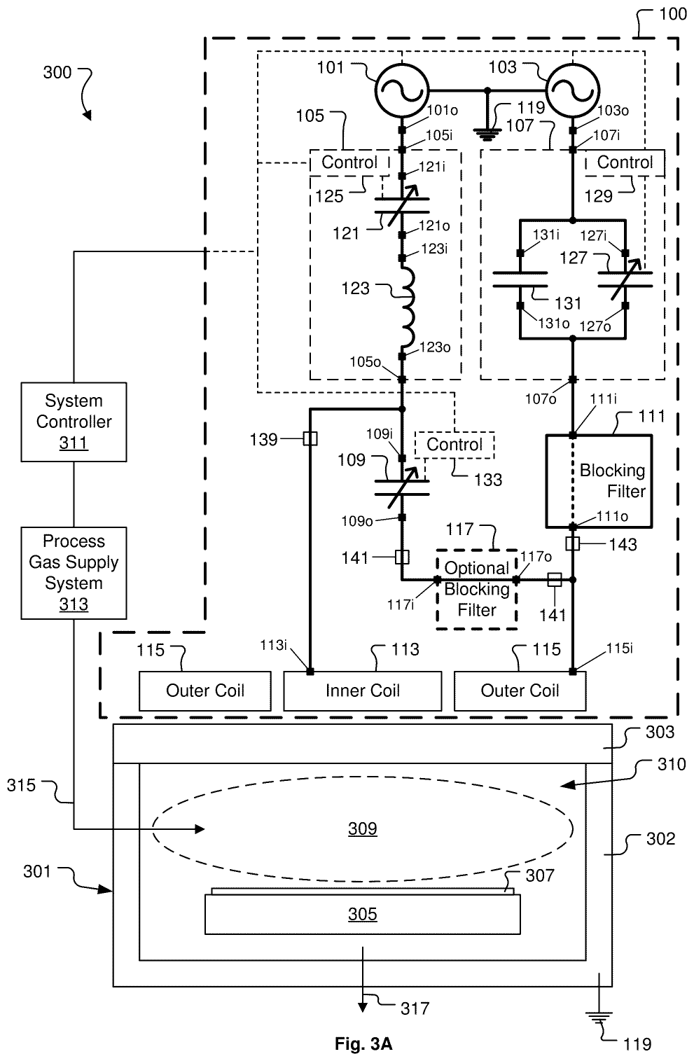

In some embodiments, a control component 125 is connected to provide for control of a capacitance setting of the first tuning variable capacitor 121. In some embodiments, the control component is a mechanical shaft that extends to a location that is accessible for manual turning of the mechanical shaft, where the manual turning of the mechanical shaft provides for changing of the capacitance setting of the first tuning variable capacitor 121. In some embodiments, the control component 125 includes a motor, e.g., stepper motor, and mechanical linkage extending between the motor and the first tuning variable capacitor 121. In some embodiments, the mechanical linkage converts rotation movement of a shaft of the motor into adjustment of the capacitance setting of the first tuning variable capacitor 121, e.g., such as by causing movement of spaced apart electrically conductive members (e.g., plates) of the first tuning variable capacitor 121 relative to each other. In some embodiments, the control component 125 is configured to provide for remote control of the capacitance setting of the first tuning variable capacitor 121 through transmission of electrical signals to the control component 125. In some embodiments, operation of the control component 125 is directed by electrical signals transmitted from a system controller 311 (see FIG. 3A), such that the capacitance setting of the first tuning variable capacitor 121 can be set remotely and/or programmatically by the system controller 311. In some embodiments, a reactance of the first reactive circuit 105 is modified by transmitting a quality factor control signal to the control component 125, where the quality factor control signal directs implementation of a specific change in the reactance of the first reactive circuit 105, such as by directing implementation of a change in the capacitance setting of the first tuning variable capacitor 121.

In some embodiments, the current splitter variable capacitor 109 has an output terminal 1090 connected to the input terminal 115i of the second coil 115. In some embodiments, a control component 133 is connected to provide for control of a capacitance setting of the current splitter variable capacitor 109. In some embodiments, the control component 133 includes a motor, e.g., stepper motor, and mechanical linkage extending between the motor and the current splitter variable capacitor 109. In some embodiments, the mechanical linkage converts rotation movement of a shaft of the motor into adjustment of the capacitance setting of the current splitter variable capacitor 109, e.g., such as by causing movement of spaced apart electrically conductive members (e.g., plates) of the current splitter variable capacitor 109 relative to each other. In some embodiments, the control component 133 is configured to provide for remote control of the capacitance setting of the current splitter variable capacitor 109 through transmission of electrical signals to the control component 133. In some embodiments, operation of the control component 133 is directed by electrical signals transmitted from the system controller 311 (see FIG. 3A), such that the capacitance setting of the current splitter variable capacitor 109 can be set remotely and/or programmatically by the system controller 311.

The capacitance setting of the current splitter variable capacitor 109 affects the impedance of the second coil 115. By adjusting the capacitance setting of the current splitter variable capacitor 109, the impedance between the first coil 113 and the second coil 115 is changed. When the capacitance setting of the current splitter variable capacitor 109 causes an increase in the impedance of the second coil 115, more of the RF signals of the first frequency generated by the first RF power source 101 will be transmitted to the first coil 113 and less of the RF signals of the first frequency generated by the first RF power source 101 will be transmitted to the second coil 115. Conversely, when the capacitance setting of the current splitter variable capacitor 109 causes a decrease in the impedance of the second coil 115, more of the RF signals of the first frequency generated by the first RF power source 101 will be transmitted to the second coil 115 and less of the RF signals of the first frequency generated by the first RF power source 101 will be transmitted to the first coil 113. In this manner, the current splitter variable capacitor 109 controls division (splitting) of the RF signals of the first frequency generated by the first RF power source 101 between the first coil 113 and the second coil 115.

In some embodiments, the second reactive circuit 107 includes an input terminal 107i connected to an output terminal 103o of the second RF power source 103. The second reactive circuit 107 includes a second tuning variable capacitor 127 that has an input terminal 127i connected to the input terminal 107i of the second reactive circuit 107, and in turn to the output terminal 103o of the second RF power source 103. The second tuning variable capacitor 127 has an output terminal 127o connected to an output terminal 107o of the second reactive circuit 107. The second reactive circuit 107 also includes a capacitor 131 connected in parallel with the second tuning variable capacitor 127. Specifically, an input terminal 131i of the capacitor 131 is connected to the input terminal 107i of the second reactive circuit 107, and in turn to the output terminal 103o of the second RF power source 103. The capacitor 131 has an output terminal 131o connected to the output terminal 107o of the second reactive circuit 107. The capacitor 131 is referred to herein as a parallel capacitor. The output terminal 107o of the second reactive circuit 107 is connected to convey the RF signals of the second frequency generated by the second RF power source 103 to the input terminal 115i of the second coil 115.

In some embodiments, a control component 129 is connected to provide for control of a capacitance setting of the second tuning variable capacitor 127. In some embodiments, the control component 129 is a mechanical shaft that extends to a location that is accessible for manual turning of the mechanical shaft, where the manual turning of the mechanical shaft provides for changing of the capacitance setting of the second tuning variable capacitor 127. In some embodiments, the control component 129 includes a motor, e.g., stepper motor, and mechanical linkage extending between the motor and the second tuning variable capacitor 127. In some embodiments, the mechanical linkage converts rotation movement of a shaft of the motor into adjustment of the capacitance setting of the second tuning variable capacitor 127, e.g., such as by causing movement of spaced apart electrically conductive members (e.g., plates) of the second tuning variable capacitor 127 relative to each other. In some embodiments, the control component 129 is configured to provide for remote control of the capacitance setting of the second tuning variable capacitor 127 through transmission of electrical signals to the control component 129. In some embodiments, operation of the control component 129 is directed by electrical signals transmitted from the system controller 311 (see FIG. 3A), such that the capacitance setting of the second tuning variable capacitor 127 can be set remotely and/or programmatically by the system controller 311. In some embodiments, a reactance of the second reactive circuit 107 is modified by transmitting a quality factor control signal to the control component 129, where the quality factor control signal directs implementation of a specific change in the reactance of the second reactive circuit 107, such as by directing implementation of a change in the capacitance setting of the second tuning variable capacitor 127.

In some embodiments, the RF signals of the second frequency generated by the second RF power source 103 are conveyed through a blocking filter 111 in route to the input terminal 115i of the second coil 115. The blocking filter 111 is configured to prevent the RF signals of the first frequency generated by the first RF power source 101 from traveling to the second RF power source 103. In this manner, the blocking filter 111 supports conveyance of the portion of the RF signals of the first frequency generated by the first RF power source 101 that travel through the output terminal 1090 of the current splitter variable capacitor 109 to the second coil 115. The blocking filter 111 includes an input terminal 111i and an output terminal 1110, where the input terminal 111i is connected to the output terminal 107o of the second reactive circuit 107, and where the output terminal 1110 is connected to the input terminal 115i of the second coil 115. In some embodiments, the blocking filter 111 includes a capacitor 135 and an inductor 137 connected in parallel with each other between the input terminal 111i and the output terminal 1110 of the blocking filter 111. Specifically, the capacitor 135 has an input terminal 135i connected to the input terminal 111i of the blocking filter 111, and an output terminal 1350 connected to the output terminal 1110 of the blocking filter 111. Also, the inductor 137 has an input terminal 137i connected to the input terminal 111i of the blocking filter 111, and an output terminal 1370 connected to the output terminal 1110 of the blocking filter 111. In various embodiments, the blocking filter 111 can be configured differently from what is shown in the example of FIG. 1, so long as the blocking filter 111 provides for transmission of the RF signals of the second frequency from the second RF power source 103 to the second coil 115, while blocking transmission of the RF signals of the first frequency from the first RF power source 101 to the second RF power source 103.

In some embodiments, as an option, a blocking filter 117 is connected between the current splitter variable capacitor 109 and the second coil 115. Specifically, an input terminal 117i of the blocking filter is connected to the output terminal 1090 of the current splitter variable capacitor 109, and an output terminal 1170 of the blocking filter 117 is connected to the input terminal 115i of the second coil 115. In some embodiments, the blocking filter 117 is configured like the blocking filter 111 to include a capacitor and an inductor connected in parallel with each other, similar to the capacitor 135 and the inductor 137. In some embodiments, the portion of the RF signals of the first frequency generated by the first RF power source 101 that are conveyed through the current splitter variable capacitor 109 are in turn conveyed through the blocking filter 117 in route to the input terminal 115i of the second coil 115. The blocking filter 117 is configured to prevent the RF signals of the second frequency generated by the second RF power source 103 from traveling to the first RF power source 101. In this manner, the blocking filter 117 supports conveyance of the RF signals of the second frequency generated by the second RF power source 103 to the second coil 115. In various embodiments, the blocking filter 117 can be configured in various ways, so long as the blocking filter 117 provides for transmission of the RF signals of the first frequency from the first RF power source 101 to the second coil 115, while blocking transmission of the RF signals of the second frequency from the second RF power source 103 to the first RF power source 101.

In some embodiments, the RF power supply system 100 includes one or more sensors for measuring an amount of RF power delivered to the first coil 113 and/or an amount of RF power delivered to the second coil 115. For example, in some embodiments, a V/I (voltage/current) sensor 139 is connected to provide for measurement of the amount RF power delivered from the first RF power source 101 to the first coil 113. In some embodiments, the V/I sensor 139 is connected between the output terminal 105o of the first reactive circuit 105 and the input terminal 113i of the first coil 113. In some embodiments, another V/I sensor 141 is connected to provide for measurement of the amount RF power delivered from the first RF power source 101 to the second coil 115. In some embodiments, the V/I sensor 141 is connected between the output terminal 1090 of the current splitter variable capacitor 109 and the input terminal 115i of the second coil 115. Also, in some embodiments, the V/I sensor 141 is connected between the output terminal 1170 of the blocking filter 117 and the input terminal 115i of the second coil 115. In some embodiments, another V/I sensor 143 is connected to provide for measurement of the amount RF power delivered from the second RF power source 103 to the second coil 115. In some embodiments, the V/I sensor 143 is connected between the output terminal 1110 of the blocking filter 111 and the input terminal 115i of the second coil 115. Also, in some embodiments, the V/I sensor 141 is connected between the output terminal 107o of the second reactive circuit 107 and the input terminal 115i of the second coil 115.

In some embodiments, the V/I sensor 139 is connected to measure a voltage and a current present on an electrical conductor in the RF signal delivery path from the first RF power source 101 to the first coil 113. Also, in some embodiments, the V/I sensor 141 is connected to measure a voltage and a current present on an electrical conductor in the RF signal delivery path from the first RF power source 101 to the second coil 115. Also, in some embodiments, the V/I sensor 143 is connected to measure a voltage and a current present on an electrical conductor in the RF signal delivery path from the second RF power source 103 to the second coil 115. In some embodiments, each of the V/I sensors 139, 141, and 143 is configured to measure a root-mean-square (RMS) voltage (Vᵣₘₛ), an RMS current (iᵣₘₛ), and a phase angle (φ) between the measured RMS voltage (Vᵣₘₛ) and measured RMS current (iᵣₘₛ) at a given time. In some embodiments, each of the V/I sensors 139, 141, and 143 is also configured to determine an RF power (P) being transmitted through the corresponding electrical conductor at a given time by using the measured RMS voltage (Vᵣₘₛ), the measured RMS current (iᵣₘₛ), and the phase angle (φ) between the measured RMS voltage (Vᵣₘₛ) and the measured RMS current (iᵣₘₛ) at the given time as follows: P=(Vᵣₘₛ)(iᵣₘₛ)cos(φ). It should be understood that in various embodiments, each of the V/I sensors 139, 141, and 143 can be configured to determine the real-time RF power being transmitted through the corresponding electrical conductor at any given time using essentially any available electrical measurement or measurement-computation technique. In some embodiments, a signal indicating the RF power (P) determined by the V/I sensor 139, 141, 143 at any given time is conveyed to the system controller 311 (see FIG. 3A) through an electrical signal connection. Also, in some embodiments, signals indicating the measured RMS voltage (Vᵣₘₛ), the measured RMS current (iᵣₘₛ), and the phase angle (q) between the measured RMS voltage (Vᵣₘₛ) and measured RMS current (iᵣₘₛ) at any given time are conveyed from the V/I sensor 130, 141, 143 to the system controller 311 through an electrical signal connection.

In some embodiments, the V/I sensors 139, 141, 143 can be used to determine the amount of RF power that is being transmitted to each of the first coil 113 and the second coil 115. In some embodiments, information obtained from the V/I sensors 139, 141, 143 enable the system controller 311 to determine how to adjust the capacitance setting of the current splitter variable capacitor 109 to achieve a target RF current ratio between the first coil 113 and the second coil 115. In some embodiments, the system controller 311 is configured to use one or more of the RF power measurement(s) provided by the V/I sensors 139, 141, 143 as a feedback signal to control the capacitance setting of the current splitter variable capacitor 109, by way of the control component 133, so that a target amount of RF power corresponding to the RF signals of the first frequency is transmitted to the second coil 115 from the first RF power source 101. For example, in some embodiments, a plasma processing recipe specifies an initial setpoint for the capacitance setting of the current splitter variable capacitor 109 and a target RF parameter (voltage, current, and/or power) for each of the first coil 113 and the second coil 115. Then, during performance of the plasma processing recipe on the wafer, the measurements provided by the V/I sensors 139, 141, and 143 are used by the system controller 311 as feedback signals to control the capacitance setting of the current splitter variable capacitor 109 to achieve and maintain the target RF parameter (voltage, current, and/or power) for each of the first coil 113 and the second coil 115. In this manner, a closed-loop feedback control process is implemented using the system controller 311, the control component 133, the current splitter variable capacitor 109, and one or more of the V/I sensors 139, 141, and/or 143.

FIG. 3A shows an example plasma processing system 300 that utilizes the RF power supply system 100, in accordance with some embodiments. FIG. 3A shows an example vertical cross-section diagram through an example plasma processing chamber 301. The plasma processing chamber 301 includes an outer structure 302, e.g., side and bottom structures, and an upper window structure 303. The upper window structure 303 is formed of a material, e.g., quartz or similar material, that provides for transmission of RF power from the first coil 113 and the second coil 115 into a plasma processing region 310 within the plasma processing chamber 301. A substrate support structure 305 is disposed within the plasma processing region 310 to provide for support a substrate 307 during plasma processing of the substrate 307. The substrate support structure 305 is configured to hold the substrate 307 in exposure to the plasma processing region 310 during plasma processing operations. The plasma processing chamber 301 is connected to the reference ground potential 119.

The plasma processing system 300 is an inductively coupled system in which RF power is transmitted from the first coil 113 and the second coil 115 into the plasma processing region 310. In the example plasma processing system 300, the first coil 113 is an inner coil, and the second coil 115 is an outer coil. FIG. 3B shows a top view of the first coil 113 and the second coil 115 in the plasma processing system 300, in accordance with some embodiments. In the example of FIG. 3B, the first coil 113 (inner coil) includes a pair of interleaved spiral-shaped coils 113A and 113B. Each of the coils 113A and 113B has a respective first end connected to receive RF signals from the output terminal 105o of the first reactive circuit 105. Each of the coils 113A and 113B has a respective second end connected to the reference ground potential 119. Also, in the example of FIG. 3B, the second coil 115 (outer coil) includes a pair of interleaved spiral-shaped coils 115A and 115B that are collectively positioned to circumscribe the coils 113A and 113B of the first coil 113 (inner coil). Each of the coils 115A and 115B has a respective first end connected to receive RF signals from the output terminal 1110 of the blocking filter 111 and from the output terminal 1090 of the current splitter variable capacitor 109 (either directly or by way of the optional blocking filter 117). Each of the coils 115A and 115B has a respective second end connected to the reference ground potential 119. In various embodiments, each of the first coil 113 and the second coil 115 can have essentially any configuration that is suitable for transmitting RF power through the upper window structure 303 and into the plasma processing region 310. In various embodiments, each of the first coil 113 and the second coil 115 can have any number of turns and any cross-section size and shape (circular, oval, rectangular, trapezoidal, etc.) as appropriate to provide for transmission of RF power through the upper window structure 303 and into the plasma processing region 310.

The plasma processing region 310 is fluidly connected to a process gas supply system 313, such that one or more process gas(es) can be supplied in a controlled manner to the plasma processing region 310, as represented by arrow 315. The process gas supply system 313 includes one or more process gas sources and an arrangement of valves and mass flow controllers to enable provision of the one or more process gas(es) to the plasma processing region 310 with a controlled flow rate and with a controlled flow time. Also, in various embodiments, the one or more process gas(es) are delivered to the plasma processing region 310 in both a temporally controlled manner and a spatially controlled manner relative to the substrate support structure 305 and substrate 307 held thereon. The plasma processing system 300 also includes an exhaust system that provides for controlled removal of process gas(es) from the plasma processing region 310, as indicated by arrow 317. The plasma processing system 300 operates by having the process gas supply system 313 flow one or more process gases into the plasma processing region 310, and by transmitting RF power from the first coil 113 and/or the second coil 115 into the plasma processing region 310 to transform the one or more process gases into a plasma 309 (represented by the dashed oval region) in the plasma processing region 310. In some embodiments, the system controller 311 is connected to control operation of the process gas supply system 313 and to control operation of the RF power supply system 100.

The plasma 309 is generated to cause a change to the substrate 307 in a controlled manner. In various fabrication processes, the change to the substrate 307 can be a change in material or surface condition on the substrate 307 For example, in various fabrication processes, the change to the substrate 307 can include one or more of etching of a material from the substrate 307, deposition of a material on the substrate 307, or modification of material present on the substrate 307. It should be understood that the plasma processing system 300 can be any type of plasma processing system in which RF power is transmitted from the first coil 113 and the second coil 115 disposed outside the plasma processing chamber 301 to a process gas within the plasma processing region 310 to generate the plasma 309 within the plasma processing region 310.

In some embodiments, the substrate 307 is a semiconductor wafer undergoing a fabrication procedure. However, it should be understood that in various embodiments, the substrate 307 can be essentially any type of substrate that is subjected to a plasma-based fabrication process. For example, in some embodiments, the substrate 307 as referred to herein can be a substrate formed of silicon, sapphire, GaN, GaAs or SiC, or other substrate materials, and can include glass panels/substrates, metal foils, metal sheets, polymer materials, or the like. Also, in various embodiments, the substrate 307 referred to herein may vary in form, shape, and/or size. For example, in some embodiments, the substrate 307 referred to herein may correspond to a 200 mm (millimeters) diameter semiconductor wafer, a 300 mm diameter semiconductor wafer, or a 450 mm diameter semiconductor wafer, among other semiconductor wafer sizes. Also, in some embodiments, the substrate 307 referred to herein may correspond to a non-circular substrate, such as a rectangular substrate for a flat panel display, or the like, among other shapes.

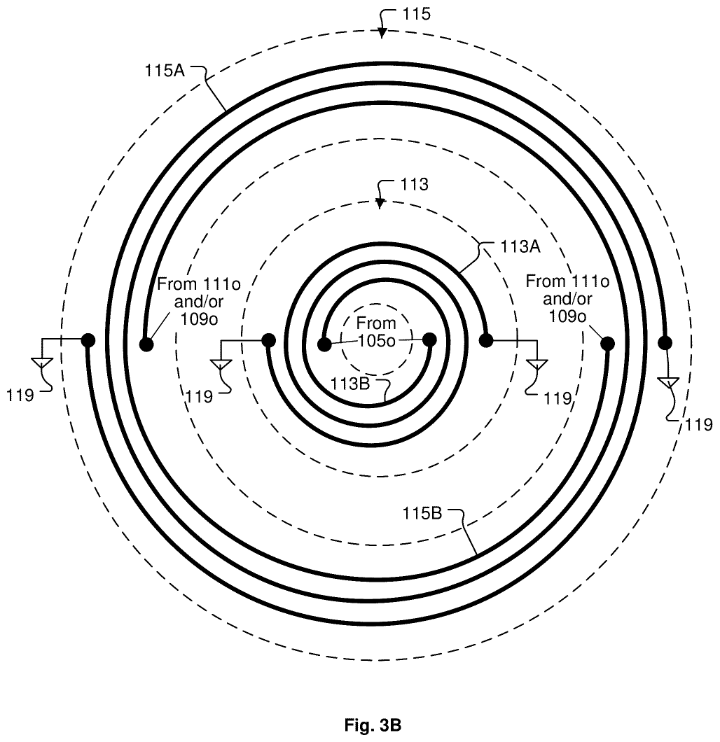

FIG. 4 shows a flowchart of a method for supplying RF power to a plasma processing system, in accordance with some embodiments. The method includes an operation 401 for generating RF signals of a first frequency (e.g., such as by operating the first RF power source 101). The method also includes an operation 403 for supplying a first portion of the RF signals of the first frequency to a first coil (e.g., 113). The method also includes an operation 405 for supplying a second portion of the RF signals of the first frequency to a second coil (e.g., 115). In some embodiments, the method includes using a current splitter variable capacitor (e.g., 109) to control an amount of the first portion of the RF signals of the first frequency and an amount of the second portion of the RF signals of the first frequency. The method also includes an operation 407 for generating RF signals of a second frequency (e.g., such as by operating the second RF power source 103). The method also includes an operation 409 for supplying the RF signals of the second frequency to the second coil (e.g., 115). In some embodiments, the method includes using a blocking filter (e.g., 111) to prevent the RF signals of the first frequency from traveling to a source of the RF signals of the second frequency (e.g., to prevent the RF signals generated by the first RF power source 101 from traveling to the second RF power source 103).

In some embodiments, the method includes an operation for controlling a capacitance setting of the current splitter variable capacitor (e.g., 109) to increase the amount of the second portion of the RF signals of the first frequency, as generated by the first RF power source (e.g., 101), that are transmitted to the second coil (e.g., 115) to support ignition/striking of a plasma being driven by the second coil (e.g., 115). Also, in some of these embodiments, the method includes an operation for controlling the capacitance setting of the current splitter variable capacitor (e.g., 109) to decrease the amount of the second portion of the RF signals of the first frequency, as generated by the first RF power source (e.g., 101), that are transmitted to the second coil (e.g., 115) after ignition/striking of the plasma. In some embodiments, the method includes an operation for controlling a capacitance setting of the current splitter variable capacitor (e.g., 109) to control the amount of the second portion of the RF signals of the first frequency, as generated by the first RF power source (e.g., 101), that are transmitted to the second coil (e.g., 115) to support stability of a plasma being driven by the second coil (e.g., 115). In some embodiments, the method includes an operation for measuring an amount of RF power delivered to the second coil (e.g., 115) by the second portion of the RF signals of the first frequency as generated by the first RF power source (e.g., 101). Also, in these embodiments, the method includes an operation for using the measured amount of RF power as a feedback signal to control a capacitance setting of the current splitter variable capacitor (e.g., 109) so that a target amount of RF power is delivered to the second coil (e.g., 115) by the second portion of the RF signals of the first frequency as generated by the first RF power source (e.g., 101).

In some embodiments, the first frequency of the RF signals generated by the first RF power source 101 is about 13 megaHertz (MHZ), and the second frequency of the RF signals generated by the second RF power source 103 is about 2 MHZ. In these embodiments, the capacitance setting of the current splitter variable capacitor 109 is controlled within a range extending from about 5 picoFarads (pF) to about 500 pF. Also, in some of these embodiments, the capacitance setting of the first tuning variable capacitor 121 is controlled within a range extending from about 5 pF to about 1000 pF, with the inductor 123 having an inductance within a range extending from about 300 nanoHenrics (nH) to about 1000 nH. Also, in some of these embodiments, the capacitance setting of the second tuning variable capacitor 127 is controlled within a range extending from about 5 pF to about 2000 pF, with the capacitor 131 having a capacitance within a range extending from about 2000 pF to about 3500 pF. Also, in some of these embodiments, the blocking filter 111 is configured with the capacitor 135 having a capacitance within a range extending from about 50 pF to about 500 pF, and with the inductor 137 having an inductance within a range extending from about 200 nH to about 2000 nH. Also, in some of these embodiments, the optional blocking filter 117 is configured similar to the blocking filter 111.

In some embodiments, the plasma processing system 300 is programmed by way of the system controller 311 to perform plasma processing recipes that include generation of the plasma 309 in a plasma mode in which it is difficult to ignite/strike and sustain the plasma 309 using transmission of just the RF signals of the second frequency to the second coil 115 in combination with transmission of the RF signals of the first frequency to just the first coil 113. For example, with some plasma processing recipes and prescribed plasma modes, the RF signals of the second frequency, e.g., 2 MHz, as generated by the second RF power source 103 do not in themselves provide sufficient RF power to ignite/strike and sustain the plasma driven by the outer coil 115. Therefore, for these plasma processing recipes and prescribed plasma modes, the current splitter variable capacitor 109 is controlled by way of the control component 133 to divert some of the RF signals of the first frequency, e.g., 13 MHZ, to the outer coil 115 to assist with ignition/striking and sustaining of the plasma 309 being driven by the outer coil 115.

In various plasma processing recipes, the plasma 309 can be generated in either an E mode in which the plasma 309 is being driven primarily by capacitive fields between the coil 113/115 and the plasma 309, or in an H-mode in which the plasma 309 is being driven primarily by magnetic fields generated by the coil 113/115. In some situations, when the plasma 309 is to be generated in the H-mode, the RF power supplied by the RF signals of the second frequency transmitted from the second RF power source 103 to the second coil 115 is not sufficient to ignite/strike and sustain the plasma 309. Also, due to transition regions within the plasma 309 generation, it would be necessary to increase the RF power supplied by the RF signals of the second frequency transmitted from the second RF power source 103 to the second coil 115 by an order of magnitude, e.g., from about 300 Watts to over 2 kiloWatts, in order to ignite/strike and sustain the plasma 309. However, increasing the RF power supplied by the RF signals of the second frequency to such a high level would result in driving of very high current through the second coil 115, which is not allowed. For example, driving of very high current through the second coil 115 can increase the voltage on the second coil 115 to an unacceptable level that causes problematic plasma sputtering of the upper window structure 303. Therefore, in such situations, generation of the plasma 309 in the H-mode cannot be reliably done by simple increasing the RF power supplied by the RF signals of the second frequency from the second RF power source 103 to the second coil 115. The RF power supply system 100 provides a solution in this situation that allows for reliable ignition/striking and sustaining of the plasma 309 in the H-mode without having to drive unacceptably high current through the second coil 115. For example, in this situation, the system controller 311 and control component 133 operate to set the capacitance of the current splitter variable capacitor 109 to divert a sufficient amount of the RF signals of the first frequency as generated by the first RF power source 101 to the second coil 115 to augment the RF power provided by the RF signals of the second frequency that are supplied to the second coil 115 from the second RF power source 103 in order to support igniting/striking and sustaining of the plasma 309 in the H-mode, without causing an unacceptably high voltage on the second coil 115 that could cause sputtering of the upper window structure 303.

In various embodiments, the capacitance setting of the current splitter variable capacitor 109 can be changed between plasma processing steps as needed. For example, a plasma processing recipe can include a processing step in which a majority of the RF signals of the first frequency are transmitted to the first coil 113, followed by another processing step in which some of the RF signals of the first frequency are diverted, by way of the current splitter variable capacitor 109, to the second coil 115 to support coupling of the RF signals of the second frequency from the second coil 115 to the plasma 309. Also, in some embodiments, the system controller 311 is programmed to control the capacitance setting of the current splitter variable capacitor 109, by way of the control component 133, so that a sufficiently large portion of the RF signals of the first frequency is transmitted from the first RF power source 101 to the second coil 115 for an ignition/striking phase of the plasma 309 generation, followed by a reduction in the portion of the RF signals of the first frequency transmitted from the first RF power source 101 to the second coil 115 after ignition/striking of the plasma 309, such that the voltage on the second coil 115 is maintained below a level, e.g., 1500 V, that could cause plasma sputtering of the upper window structure 303. It should be understood that the programmable ability to divert some of the RF signals of the first frequency to the second coil 115 that is provided by the RF power supply system 100, and particularly by the current splitter variable capacitor 109, provides for increased reliability of plasma 309 ignition/strike, improved plasma 309 stability during the plasma processing operation, and sufficiently low voltage on the coil 115 to prevent/reduce plasma sputtering of the upper window structure 303.

The RF power supply system 100 disclosed herein provides a way to split the RF power provided by the RF signals of the first frequency, e.g., 13 MHZ, between the first coil 113, e.g., inner coil, and the second coil 115, e.g., outer coil. The RF power supply system 100 is particularly useful when each of the first RF power source 101 and the second RF power source 103 is a respective direct-drive RF signal generator 200. The splitting of a portion of the RF signals of the first frequency to the second coil 115 enables use of the direct-drive RF signal generator 200 for each of the first RF power source 101 and the second RF power source 103 in situations in which the RF power provided by the RF signals of the second frequency to the second coil 115 results in no plasma 309 ignition, plasma 309 instability, and/or H-mode plasma 309 sustainability issues.

In some embodiments, by adding a small amount of the RF current corresponding to the RF signals of the first frequency, e.g., 13 MHZ, to the second coil 115, both plasma 309 ignition/strike is more likely and the plasma 309 stability window is increased. Also, in some embodiments, H-mode sustainment of the plasma 309 is more likely because the RF current corresponding to the RF signals of the first frequency, e.g., 13 MHZ, that is supplied to the second coil 115 aids in putting the plasma 309 into the H-mode, where the RF current corresponding to the RF signals of the second frequency, e.g., 2 MHZ, that is supplied to the second coil 115 is unable on its own to put the plasma 309 into the H-mode. Additionally, by adding a small amount of the RF current corresponding to the RF signals of the first frequency, e.g., 13 MHZ, to the second coil 115, it is possible to control a spatial distribution of plasma 309 properties, such as ion density, electron density, and electron temperature, among other properties of the plasma 309.

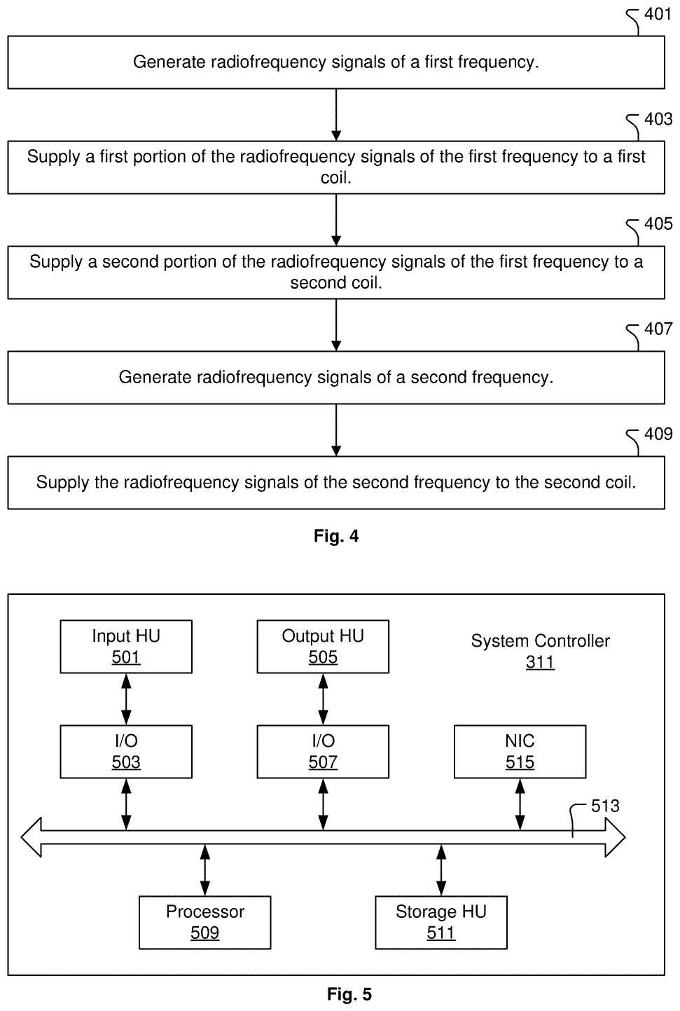

FIG. 5 shows a diagram of the system controller 311, in accordance with some example embodiments. In some embodiments, the system controller 311 includes a processor 509, a storage hardware unit (HU) 511 (e.g., memory), an input HU 501, an output HU 505, an input/output (I/O) interface 503, an I/O interface 507, a network interface controller (NIC) 515, and a data communication bus 513. The processor 509, the storage HU 511, the input HU 501, the output HU 505, the I/O interface 503, the I/O interface 507, and the NIC 515 are in data communication with each other by way of the data communication bus 513. Examples of the input HU 501 include a mouse, a keyboard, a stylus, a data acquisition system, a data acquisition card, etc. Examples of the output HU 505 include a display, a speaker, a device controller, etc. Examples of the NIC 515 include a network interface card, a network adapter, etc. In various embodiments, the NIC 515 is configured to operate in accordance with one or more communication protocols and associated physical layers, such as Ethernet and/or EtherCAT, among others. Each of the I/O interfaces 503 and 507 is defined to provide compatibility between different hardware units coupled to the I/O interface. For example, the I/O interface 503 can be defined to convert a signal received from the input HU 501 into a form, amplitude, and/or speed compatible with the data communication bus 513. Also, the I/O interface 507 can be defined to convert a signal received from the data communication bus 513 into a form, amplitude, and/or speed compatible with the output HU 505. Although various operations described herein are performed by the processor 509 of the system controller 311, it should be understood that in some embodiments various operations can be performed by multiple processors of the system controller 311 and/or by multiple processors of multiple computing systems connected to the system controller 311.

In various embodiments, the plasma processing system 300 is integrated with electronics for controlling its operation before, during, and after processing of the substrate 307, where the electronics are implemented within the system controller 311 that is configured and connected to control various components and/or sub-parts of the plasma processing system 300, including the RF power supply system 100. Depending on substrate 307 processing requirements and/or the particular configuration of the plasma processing system 300, the system controller 311 is programmed to control any process and/or component disclosed herein, including delivery of process gas(es) by the process gas supply system 313, temperature settings (e.g., heating and/or cooling), pressure settings, vacuum settings, power settings, RF power supply system 100 settings, electrical signal frequency settings, gas flow rate settings, fluid delivery settings, positional and operation settings, substrate 307 transfers into and out of the plasma processing chamber 301 and/or into and out of load locks connected to or interfaced with the plasma processing system 300, among others.

In various embodiments, the system controller 311 is defined as electronics having various integrated circuits, logic, memory, and/or software that direct and control various tasks/operations, such as receiving instructions, issuing instructions, controlling device operations, enabling cleaning operations, enabling endpoint measurements, enabling metrology measurements (optical, thermal, electrical, etc.), among other tasks/operations. In some embodiments, the integrated circuits within the system controller 311 include one or more of firmware that stores program instructions, a digital signal processor (DSP), an Application Specific Integrated Circuit (ASIC) chip, a programmable logic device (PLD), one or more microprocessors, and/or one or more microcontrollers that execute program instructions (e.g., software), among other computing devices. In some embodiments, the program instructions are communicated to the system controller 311 in the form of various individual settings (or program files), defining operational parameters for carrying out a process on the substrate 307 within the plasma processing system 300. In some embodiments, the operational parameters are included in a recipe defined by process engineers to accomplish one or more processing steps during the fabrication of one or more layers, materials, metals, oxides, silicon, silicon dioxide, surfaces, circuits, and/or dies on the substrate 307.

In some embodiments, the system controller 311 is a part of, or connected to, a computer that is integrated with, or connected to, the plasma processing system 300, or that is otherwise networked to the plasma processing system 300, or a combination thereof. For example, in some embodiments, the system controller 311 is implemented in a “cloud” or all or a part of a fab host computer system, which allows for remote access for control of substrate 307 processing by the plasma processing system 300. The system controller 311 enables remote access to the plasma processing system 300 to provide for monitoring of current progress of fabrication operations, provide for examination of a history of past fabrication operations, provide for examination of trends or performance metrics from a plurality of fabrication operations, provide for changing of processing parameters, provide for setting of subsequent processing steps, provide for specification of RF power supply system 100 operational parameters, and/or provide for initiation of a new substrate fabrication process.

In some embodiments, a remote computer, such as a server computer system, provides process recipes to the system controller 311 over a computer network, which includes a local network and/or the Internet. The remote computer includes a user interface that enables entry or programming of parameters and/or settings, which are then communicated to the system controller 311 from the remote computer. In some examples, the system controller 311 receives instructions in the form of settings for processing the substrate 307 within the plasma processing system 300. It should be understood that the settings are specific to a type of process to be performed on the substrate 307 and a type of tool/device/component that the system controller 311 interfaces with or controls. In some embodiments, the system controller 311 is distributed, such as by including one or more discrete system controller(s) 311 that are networked together and synchronized to work toward a common purpose, such as operating the plasma processing system 300 to perform a prescribed process on the substrate 307. An example of a distributed system controller 311 for such purposes includes one or more integrated circuits on a chamber in communication with one or more integrated circuits located remotely (such as at a platform level or as part of a remote computer) that combine to control a process in the chamber. Also, depending on a process operation to be performed by the plasma processing system 300, the system controller 311 communicates with various entities through a semiconductor manufacturing factory, such as with one or more of other tool circuits or modules, other tool components, cluster tools, other tool interfaces, adjacent tools, neighboring tools, distributed tools, a main computer, another controller, or tools used in material transport that bring containers of substrates 307 to and from tool locations and/or load ports in the semiconductor manufacturing factory.

The various embodiments described herein may be practiced in conjunction with various computer system configurations including hand-held hardware units, microprocessor systems, microprocessor-based or programmable consumer electronics, minicomputers, mainframe computers and the like. The various embodiments described herein can also be practiced in conjunction with distributed computing environments where tasks are performed by remote processing hardware units that are linked through a computer network. It should also be understood that the various embodiments disclosed herein include performance of various computer-implemented operations involving data stored in computer systems. These computer-implemented operations are those that manipulate physical quantities. In various embodiments, the computer-implemented operations are performed by either a general purpose computer or a special purpose computer. In some embodiments, the computer-implemented operations are performed by a selectively activated computer, and/or are directed by one or more computer programs stored in a computer memory or obtained over a computer network. When computer programs and/or digital data is obtained over the computer network, the digital data may be processed by other computers on the computer network, e.g., a cloud of computing resources. The computer programs and digital data are stored as computer-readable code on a non-transitory computer-readable medium. The non-transitory computer-readable medium is any data storage hardware unit, e.g., a memory device, etc., that stores data, which is thereafter readable by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), digital video/versatile disc (DVD), magnetic tapes, and other optical and non-optical data storage hardware units. In some embodiments, the computer programs and/or digital data are distributed among multiple computer-readable media located in different computer systems within a network of coupled computer systems, such that the computer programs and/or digital data is executed and/or stored in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A radiofrequency power supply system, comprising:
a first coil;
a second coil;
a first radiofrequency power source connected to supply radiofrequency signals of a first frequency to both the first coil and the second coil;
a current splitter variable capacitor connected to control a division of the radiofrequency signals of the first frequency between the first coil and the second coil; and
a second radiofrequency power source connected to supply radiofrequency signals of a second frequency to the second coil.

2. The radiofrequency power supply system as recited in claim 1, further comprising:
a first reactive circuit, the first radiofrequency power source connected to supply the radiofrequency signals of the first frequency through the first reactive circuit to both the first coil and the second coil; and
a second reactive circuit, the second radiofrequency power source connected to supply the radiofrequency signals of the second frequency through the second reactive circuit to the second coil.

3. The radiofrequency power supply system as recited in claim 2, wherein the first reactive circuit includes a first tuning variable capacitor and an inductor connected in series with the first tuning variable capacitor, wherein an input terminal of the first tuning variable capacitor is connected to an output of the first radiofrequency power source, and wherein an output terminal of the inductor is connected to both the first coil and an input terminal of the current splitter variable capacitor.

4. The radiofrequency power supply system as recited in claim 3, wherein the second reactive circuit includes a second tuning variable capacitor and a parallel capacitor connected in parallel with the second tuning variable capacitor.

5. The radiofrequency power supply system as recited in claim 2, further comprising:
a blocking filter connected between the second reactive circuit and the second coil, the blocking filter configured to block the radiofrequency signals of the first frequency from traveling to the second radiofrequency power source.

6. The radiofrequency power supply system as recited in claim 5, wherein the blocking filter includes a capacitor connected in parallel with an inductor.

7. The radiofrequency power supply system as recited in claim 5, wherein the blocking filter is a first blocking filter, the radiofrequency power supply system including a second blocking filter connected between the current splitter variable capacitor and the second coil, the second blocking filter configured to block the radiofrequency signals of the second frequency from traveling to the first radiofrequency power source.

8. The radiofrequency power supply system as recited in claim 1, wherein the first radiofrequency power source is a first direct-drive radiofrequency power source, and the second radiofrequency power source is a second direct-drive radiofrequency power source.

9. The radiofrequency power supply system as recited in claim 1, further comprising:
a control component connected to control a capacitance setting of the current splitter variable capacitor in accordance with electrical control signals received from a system controller.

10. The radiofrequency power supply system as recited in claim 9, further comprising:
a first sensor connected to measure a first amount of radiofrequency power delivered to the first coil from the first radiofrequency power source; and
a second sensor connected to measure a second amount of radiofrequency power delivered to the second coil from first radiofrequency power source.

11. The radiofrequency power supply system as recited in claim 10, wherein the system controller is configured to use at least one of the first amount of radiofrequency power and the second amount of radiofrequency power as a feedback signal to generate the electrical control signals for transmission to the control component.

12. A radiofrequency power supply system, comprising:
a first radiofrequency power source having an output terminal;
a first reactive circuit having an input terminal and an output terminal, the input terminal of the first reactive circuit connected to the output terminal of the first radiofrequency power source;
a first coil connected to the output terminal of the first reactive circuit;
a current splitter variable capacitor having an input terminal and an output terminal, the input terminal of the current splitter variable capacitor connected to the output terminal of the first reactive circuit;
a second coil connected to the output terminal of the current splitter variable capacitor;
a second radiofrequency power source having an output terminal;
a second reactive circuit having an input terminal and an output terminal, the input terminal of the second reactive circuit connected to the output terminal of the second radiofrequency power source; and
a blocking filter having an input terminal and an output terminal, the input terminal of the blocking filter connected to the output terminal of the second reactive circuit, the output terminal of the blocking filter connected to the second coil.

13. The radiofrequency power supply system as recited in claim 9, wherein the blocking filter includes a capacitor having an input terminal and an output terminal, the input terminal of the capacitor connected to the input terminal of the blocking filter, the output terminal of the capacitor connected to the output terminal of the blocking filter, the blocking filter including an inductor having an input terminal and an output terminal, the input terminal of the inductor connected to the input terminal of the blocking filter, the output terminal of the inductor connected to the output terminal of the blocking filter.

14. The radiofrequency power supply system as recited in claim 9, wherein the first reactive circuit includes a first tuning variable capacitor having an input terminal and an output terminal, the input terminal of the first tuning variable capacitor connected to the input terminal of the first reactive circuit, the first reactive circuit including an inductor having an input terminal and an output terminal, the input terminal of the inductor connected to the output terminal of the first tuning variable capacitor, the output terminal of the inductor connected to the output terminal of the first reactive circuit, and
wherein the second reactive circuit includes a second tuning variable capacitor having an input terminal and an output terminal, the input terminal of the second tuning variable capacitor connected to the input terminal of the second reactive circuit, the output terminal of the second tuning variable capacitor connected to the output terminal of the second reactive circuit, the second reactive circuit including a parallel capacitor having an input terminal and an output terminal, the input terminal of the parallel capacitor connected to the input terminal of the second reactive circuit, the output terminal of the parallel capacitor connected to the output terminal of the second reactive circuit.

15. A method for supplying radiofrequency power to a plasma processing system, comprising:
generating radiofrequency signals of a first frequency;
supplying a first portion of the radiofrequency signals of the first frequency to a first coil;
supplying a second portion of the radiofrequency signals of the first frequency to a second coil;
generating radiofrequency signals of a second frequency; and
supplying the radiofrequency signals of the second frequency to the second coil.

16. The method as recited in claim 15, further comprising:
using a current splitter variable capacitor to control an amount of the first portion of the radiofrequency signals of the first frequency and an amount of the second portion of the radiofrequency signals of the first frequency.

17. The method as recited in claim 16, further comprising:
controlling a capacitance setting of the current splitter variable capacitor to increase the amount of the second portion of the radiofrequency signals of the first frequency to support ignition of a plasma being driven by the second coil; and
controlling the capacitance setting of the current splitter variable capacitor to decrease the amount of the second portion of the radiofrequency signals of the first frequency after ignition of the plasma.

18. The method as recited in claim 16, further comprising:
controlling a capacitance setting of the current splitter variable capacitor to control the amount of the second portion of the radiofrequency signals of the first frequency to support stability of a plasma being driven by the second coil.

19. The method as recited in claim 16, further comprising:
measuring an amount of radiofrequency power delivered to the second coil by the second portion of the radiofrequency signals of the first frequency; and
using the measured amount of radiofrequency power as a feedback signal to control a capacitance setting of the current splitter variable capacitor so that a target amount of radiofrequency power is delivered to the second coil by the second portion of the radiofrequency signals of the first frequency.

20. The method as recited in claim 15, further comprising:
using a blocking filter to prevent the radiofrequency signals of the first frequency from traveling to a source of the radiofrequency signals of the second frequency.
